(19) United States
(12) Patent Application Publication
(10) Pub. No.: US 2006/0056234 A1
(43) Pub. Date: Mar. 16, 2006

(54) Using a phase change memory as a shadow RAM

(76) Inventor: Tyler A. Lowrey, West Augusta, VA (US)

Correspondence Address: TROP PRUNER & HU, PC, 8554 KATY FREEWAY, SUITE 100, HOUSTON, TX, 77024, US

(21) Appl. No.: 10/939,275

(22) Filed: Sep. 10, 2004

(51) Int. Cl. G11C 11/00

(52) U.S. Cl. 365/163

(57) ABSTRACT

A processor-based system may use a volatile memory with a shadow phase change memory. The shadow phase change memory may be directly coupled to the controller. The controller may also be coupled to the volatile memory which, in turn, may, in some embodiments, be directly coupled to the phase change memory. In a standby mode, the volatile memory may be powered down. In some embodiments, faster speeds may be achieved with lower power consumption and less risk of data loss in the case of a crash or other system failure.

### BACKGROUND

This invention relates generally to processor-based systems.

Processor-based systems may include any device with a specialized or general purpose processor. Examples of such systems include personal computers, laptop computers, personal digital assistants, cell phones, cameras, web tablets, electronic games, and media devices, such as digital versatile disk players, to mention a few examples.

Conventionally, such devices use either semiconductor memory, hard disk drives, or some combination of the two as storage. One common semiconductor memory is a NAND flash device. Compared to other flash devices, it may have acceptable performance in some cases at lower costs. To improve its performance, the NAND flash may be coupled to a buffer. For example, a stack of a NAND flash device and a buffer, such as a dynamic random access memory or a static random access memory, may be sold as a packaged unit.

One problem with buffered NAND flash memory solutions for processor-based systems is that such a stack may have a larger size and space requirement than may be desirable in some applications. Another problem is that flash memories are block erased, and have slow write, and very slow erase times which tends to make them slow in some applications.

Volatile memory, such as static random access memory or dynamic random access memory, may have infinite cycle life, high reliability, and in the case of static random access memory, high speed operation. However, the drawback of volatile memory is the fact that data is lost when power is removed. Conversely, providing continuous power to these memories to retain data, negatively impacts system operating and standby power requirements, system battery life, portability of memory use, system reliability due to potential loss of power at any time (resulting in total data loss) and heat dissipation. Refreshing dynamic random access memories requires continuous reading and writing within the chip, even during standby when no system activity is ongoing. Static random access memories require less standby current, but are considerably more expensive due to the large memory cell size.

Thus, there is a need for improved processor-based systems.

### BRIEF DESCRIPTION OF THE DRAWINGS

FIG. 1 is a system depiction of one embodiment of the present invention;

FIG. 2 is a flow chart for software for one embodiment of the present invention;

FIG. 3 is a schematic depiction of a portion of an array in one embodiment of the present invention; and

FIG. 4 is a schematic and cross-sectional view of a cell in accordance with one embodiment of the present invention.

### DETAILED DESCRIPTION

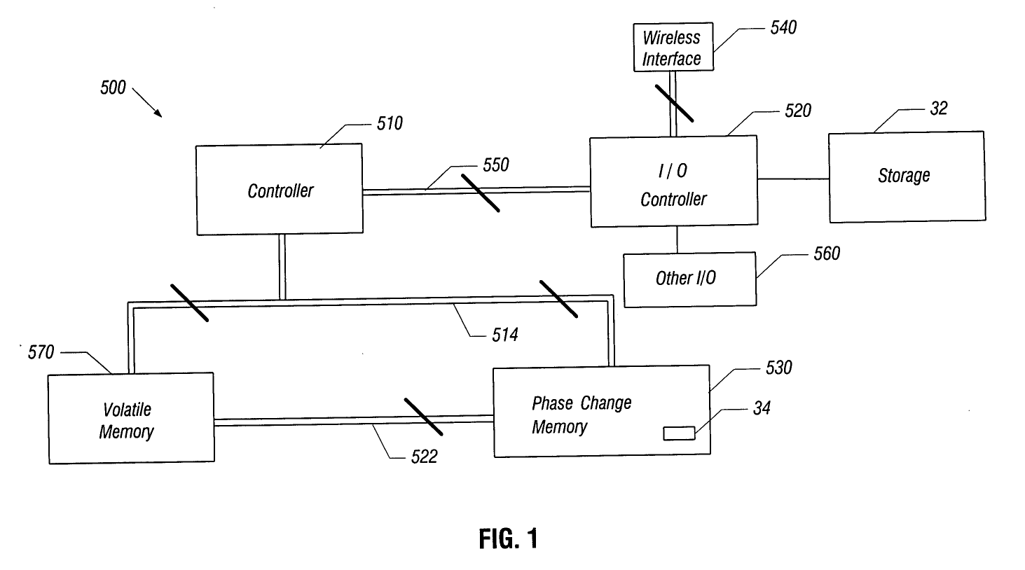

Referring to FIG. 1, a portion of a system 500 in accordance with an embodiment of the present invention is described. System 500 may be used in wireless devices such as, for example, a cellular telephone, personal digital assistant (PDA), a laptop or portable computer with wireless capability, a web tablet, a wireless telephone, a pager, an instant messaging device, a digital music player, a digital camera, or other devices that may be adapted to transmit and/or receive information wirelessly. System 500 may be used in any of the following systems: a wireless local area network (WLAN) system, a wireless personal area network (WPAN) system, or a cellular network, although the scope of the present invention is not limited in this respect.

System 500 may include a controller 510, an input/output (I/O) controller 520, a memory 530, a wireless interface 540, other I/O devices 560, and a storage 32, coupled to each other via a bus 550, a bus 514, or directly connected to the I/O controller 520. The storage 32 may be a rotating memory as one example. In some embodiments, the storage 32 may be omitted. It should be noted that the scope of the present invention is not limited to embodiments having any or all of these components.

Controller 510 may comprise, for example, one or more microprocessors, digital signal processors, micro-controllers, or the like. Memory 530 may be used to store messages transmitted to or by system 500. Memory 530 may also optionally be used to store instructions that are executed by controller 510 during the operation of system 500, and may be used to store system or user data. The instructions may be stored as digital information and the system and user data, as disclosed herein, may be stored in one section of the memory as digital data and in another section as analog memory. As another example, a given section at one time may be labeled as such and store digital information, and then later may be relabeled and reconfigured to store analog information. Memory 530 may be provided by one or more different types of memory. For example, memory 530 may comprise a volatile memory (any type of random access memory), a non-volatile memory such as a flash memory, and/or phase change memory.

The system 500 may use the wireless interface 540 to transmit and receive messages to and from a wireless communication network with a radio frequency (RF) signal. Examples of the wireless interface 540 may include an antenna, or a wireless transceiver, such as a dipole antenna, although the scope of the present invention is not limited in this respect. Also, the I/O controller 520 may deliver a voltage reflecting what is stored as either a digital output (if digital information was stored), or it may be analog information (if analog information was stored).

In FIG. 1, the controller 510 is coupled to the volatile memory 570 and to a phase change memory 530 by a bus 514. The controller 510 may directly communicate with the phase change memory 530, without any intervening buffer, via the bus 514. The volatile memory 570 and phase change memory 530 may, in some embodiments, be coupled by still another bus 522. In one embodiment, in a standby phase, the phase change memory 530 is solely operative and the volatile memory 570 is turned off. In some cases, when cache memory that is relatively fast is needed, the phase change memory 530 may operate in tandem with the volatile memory. Then, at appropriate intervals such as at user directed times, after a predetermined time period, or before power down, data stored in the volatile memory 570 may be transferred over the bus 522 or bus 514 to the phase change memory 530.

In some embodiments of the present invention, software 34 may be stored on the phase change memory which controls the operation of the phase change memory 530 relative to the volatile memory 570. In some embodiments, the software 34 may be part of an operating system. In other embodiments, the software 34 may be separate from the operating system. In general, in many embodiments, the operating system for the system 500 may be stored on the phase change memory 530.

In this way, power consumption may be reduced because the volatile memory 570 may be used only when a cache memory is needed. In other cases, the relatively fast phase change memory 530, which consumes less power and is more reliable with power loss, may be used for most activities.

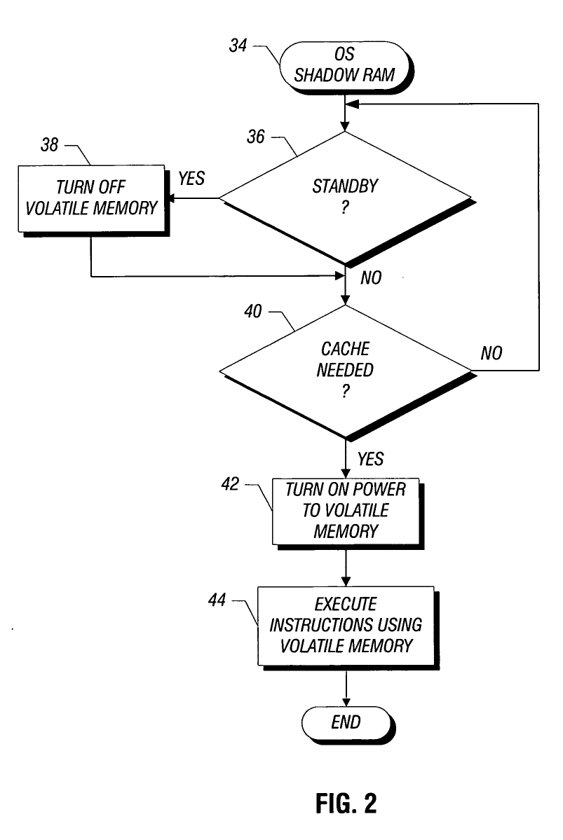

Referring to FIG. 2, the software 34 may begin, as indicated in diamond 36, by determining whether to go to a standby mode. A standby mode occurs when the system 500 is not being asked to perform any tasks. In such cases, the volatile memory 570 may be turned off as indicated in block 38. This operation may be under control of the software 34 which, in one embodiment, may be part of the operating system. Upon execution of the software 34, the controller 510 executes an instruction to turn power off in the volatile memory by a signal conveyed over the bus 514.

When a cache memory is needed, as determined in diamond 40, power may be restored to the volatile memory 570 as indicated in block 42. In some cases, power may be cut off and in other cases the memory 570 may be placed in a lower power consumption state. Generally, the volatile memory 570 may be used as a cache adjunct to the phase change memory 530 when particularly high performance and high speed is necessary. Then, instructions may be executed using the volatile memory 570 as needed as indicated in block 44. For example, various writes and reads may be executed to the volatile memory 570. After completion of those operations, the information stored in the volatile memory 570 may be erased or may be transferred to the phase change memory 530 over the bus 522 or bus 514.

Referring back to FIG. 1, in some embodiments, the volatile memory 570 may be a separate standalone integrated circuit. In other embodiments, the volatile memory 570 may be on the same integrated circuit with a controller 510 in the form, for example, of a microprocessor. In still other embodiments, the volatile memory 570 may be on the same integrated circuit with the phase change memory 530. For example, as explained hereinafter, the volatile memory 570 may be formed underneath the phase change memory 530 in one single integrated circuit.

In some embodiments, the volatile memory 570 may be dynamic random access memory and, in other embodiments, it may be static random access memory. In some cases, the volatile memory 570 may be a combination of both static random access memory and dynamic random access memory.

One situation where the arrangement shown in FIG. 1 is particularly advantageous is when it is necessary to change the operating system or the basic input/output system. Because the code can be quickly executed from phase change memory, more than one basic input/output system or operating system may be quickly implemented. Conversely, if a flash memory were utilized, relatively slow operation would result.

In some embodiments of the present invention, the use of the phase change memory 530 in conjunction with the volatile memory 570 not only improves speed and saves power, but also prevents data loss in the event of a crash. In the event of a crash, any data that is stored in the volatile memory 570 may be lost. However, in some implementations of the present invention, little or no data is stored only on the volatile memory 570.

By using the volatile memory 570 only when needed, that memory 570 may be powered down, reducing power consumption. For example, processor-based systems are used only intermittently. If data is stored during normal operation on the volatile memory 570, whether or not the system is being utilized, the volatile memory 570 continues to consume power to implement refresh cycles. By storing data in the phase change memory 530 instead, no such refresh is needed and power consumption may be reduced.

As an example, the phase change memory 530 may implement all system functions. However, when a relatively high speed, data intensive operation is implemented, such as downloading and processing an image, the downloading and processing of that image may be implemented using the volatile memory 570. As soon as the downloading is complete, and as time permits, the data on the volatile memory 570 may be transferred and stored permanently in the phase change memory 530.

While an example in a wireless application is provided above, embodiments of the present invention may also be used in non-wireless applications as well.

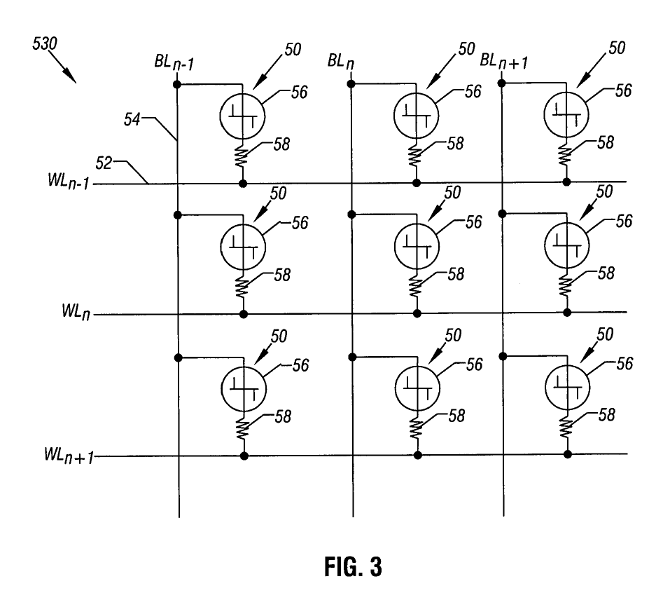

Referring to FIG. 3, a non-volatile memory 530 may include a variable resistance memory array. The memory 530, in one embodiment, may be a phase change memory. The memory 530 may include a plurality of cells 50 arranged in rows and columns. The cells 50 may include a phase change memory element 58 and a selection device 56 in one embodiment. In one embodiment, a cell 50 may be associated with a word line 52, addressable by a word line decoder and a bit line or column line 54, addressable by a bit line decoder.

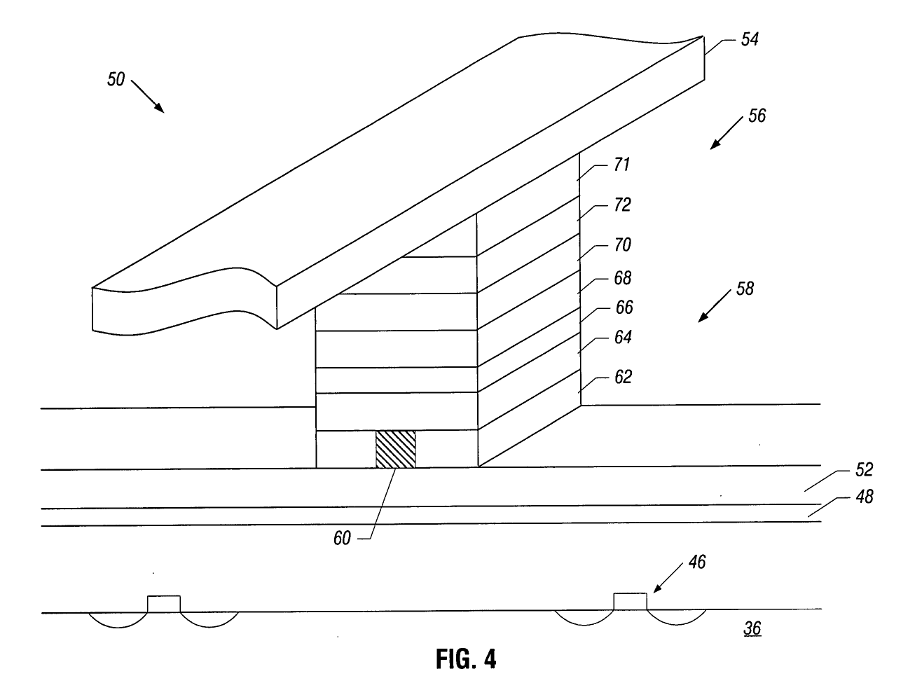

Referring to FIG. 4, a cell 50 may be formed over a substrate 36. A conductive word line 52 may be coupled to the device 56 and the element 58. An interlayer dielectric 48 may separate the integrated circuit components 46 from the phase change memory 50. The components 46 may include static random access memory (SRAM) in one embodiment. For example, the components 46 may implement the volatile memory 570 in one embodiment.

The selection device 56 may be formed of a non-programmable chalcogenide material including a top electrode 71, a chalcogenide material 72, and a bottom electrode 70 in one embodiment. The selection device 56 may be permanently in the amorphous state in one embodiment. While an embodiment is illustrated in which the selection device 56 is positioned over the phase change memory element 58, the opposite orientation may be used as well.

Conversely, the phase change memory element 58 may be capable of assuming either a set or reset state, explained in more detail hereinafter. The phase change memory element 58 may include an insulator 62, a phase change memory material 64, a top electrode 66, and a barrier film 68, in one embodiment of the present invention. A lower electrode 60 may be defined within the insulator 62 in one embodiment of the present invention.

In one embodiment, the phase change material 64 may be a phase change material suitable for non-volatile memory data storage. A phase change material may be a material having electrical properties (e.g., resistance) that may be changed through the application of energy such as, for example, heat, light, voltage potential, or electrical current.

Examples of phase change materials may include a chalcogenide material or an ovonic material. An ovonic material may be a material that undergoes electronic or structural changes and acts as a semiconductor once subjected to application of a voltage potential, electrical current, light, heat, etc. A chalcogenide material may be a material that includes at least one element from column VI of the periodic table or may be a material that includes one or more of the chalcogen elements, e.g., any of the elements of tellurium, sulfur, or selenium. Ovonic and chalcogenide materials may be non-volatile memory materials that may be used to store information.

In one embodiment, the memory material 64 may be chalcogenide element composition from the class of tellurium-germanium-antimony (TeₓGe_{y}Sb_{z}) material or a GeSbTe alloy, although the scope of the present invention is not limited to just these materials.

In one embodiment, if the memory material 64 is a non-volatile, phase change material, the memory material may be programmed into one of at least two memory states by applying an electrical signal to the memory material. An electrical signal may alter the phase of the memory material between a substantially crystalline state and a substantially amorphous state, wherein the electrical resistance of the memory material 64 in the substantially amorphous state is greater than the resistance of the memory material in the substantially crystalline state. Accordingly, in this embodiment, the memory material 64 may be adapted to be altered to a particular one of a number of resistance values within a range of resistance values to provide digital or analog storage of information.

Programming of the memory material to alter the state or phase of the material may be accomplished by applying voltage potentials to the lines 52 and 54, thereby generating a voltage potential across the memory material 64. An electrical current may flow through a portion of the memory material 64 in response to the applied voltage potentials, and may result in heating of the memory material 64.

This heating and subsequent cooling may alter the memory state or phase of the memory material 64. Altering the phase or state of the memory material 64 may alter an electrical characteristic of the memory material 64. For example, resistance of the material 64 may be altered by altering the phase of the memory material 64. The memory material 64 may also be referred to as a programmable resistive material or simply a programmable resistance material.

In one embodiment, a voltage potential difference of about 0.5 to 1.5 volts may be applied across a portion of the memory material by applying about 0 volts to a line 52 and about 0.5 to 3.0 volts to an upper line 54. A current flowing through the memory material 64 in response to the applied voltage potentials may result in heating of the memory material. This heating and subsequent cooling may alter the memory state or phase of the material.

In a “reset” state, the memory material may be in an amorphous or semi-amorphous state and in a “set” state, the memory material may be in a crystalline or semi-crystalline state. The resistance of the memory material in the amorphous or semi-amorphous state may be greater than the resistance of the material in the crystalline or semi-crystalline state. The association of reset and set with amorphous and crystalline states, respectively, is a convention. Other conventions may be adopted.

Due to electrical current, the memory material 64 may be heated to a relatively higher temperature to amorphize memory material and “reset” memory material. Heating the volume or memory material to a relatively lower crystallization temperature may crystallize memory material and “set” memory material. Various resistances of memory material may be achieved to store information by varying the amount of current flow and duration through the volume of memory material, or by tailoring the edge rate of the trailing edge of the programming current or voltage pulse.

The information stored in memory material 64 may be read by measuring the resistance of the memory material. As an example, a read current may be provided to the memory material using opposed lines 54, 52 and a resulting read voltage across the memory material may be compared against a reference voltage using, for example, a sense amplifier. The read voltage may be proportional to the resistance exhibited by the memory storage element.

In order to select a cell 50 on column 54 and row 52, the selection device 56 for the selected cell 50 at that location may be operated. The selection device 56 activation allows current to flow through the memory element 58 in one embodiment of the present invention.

In a low voltage or low field regime A, the device 56 is off and may exhibit very high resistance in some embodiments. The off resistance can, for example, range from 100,000 ohms to greater than 10 gigaohms at a bias of half the threshold voltage. The device 56 may remain in its off state until a threshold voltage VT or threshold current I_{T} switches the device 56 to a highly conductive, low resistance on state. In one embodiment, the voltage across the device 56 after turn on drops to a slightly lower voltage, called the holding voltage V_{H} and remains very close to the threshold voltage. In one embodiment of the present invention, as an example, the threshold voltage may be on the order of 1.1 volts and the holding voltage may be on the order of 0.9 volts.

After passing through the snapback region, in the on state, the device 56 voltage drop remains close to the holding voltage as the current passing through the device is increased up to a certain, relatively high, current level. Above that current level the device remains on but displays a finite differential resistance with the voltage drop increasing with increasing current. The device 56 may remain on until the current through the device 56 is dropped below a characteristic holding current value that is dependent on the size and the material utilized to form the device 56.

In some embodiments of the present invention, the selection device 56 does not change phase. It remains permanently amorphous and its current-voltage characteristics may remain the same general shape and characteristics throughout its operating life.

As an example, for a 0.5 micrometer diameter device 56 formed of TeAsGeSSe having respective atomic percents of 16/13/15/1/55, the holding current may be on the order of 0.1 to 100 micro-amps in one embodiment. Below this holding current, the device 56 turns off and returns to the high resistance regime at low voltage, low field. The threshold current for the device 56 may generally be of the same order as the holding current. The holding current may be altered by changing process variables, such as the top and bottom electrode material and the chalcogenide material. The device 56 may provide high “on current” for a given area of device compared to conventional access devices such as metal oxide semiconductor field effect transistors or bipolar junction transistors.

In some embodiments, the higher current density of the device 56 in the on state allows for higher programming current available to the memory element 58. Where the memory element 58 is a phase change memory, this enables the use of larger programming current phase change memory devices, reducing the need for aggressive sub-lithographic feature structures and the commensurate process complexity, cost, process variation, and device parameter variation.

One technique for addressing the phase change memory array uses a voltage V applied to the selected column and a zero voltage applied to the selected row. For the case where the device 58 is a phase change memory, the voltage V is chosen to be greater than the access device 56 maximum threshold voltage plus the memory element 58 reset maximum threshold voltage, but less than two times the device 56 minimum threshold voltage. In other words, the maximum threshold voltage of the device 56 plus the maximum reset threshold voltage of the device 58 may be less than V and V may be less than two times the minimum threshold voltage of the device 56 in some embodiments. All of the unselected rows and columns may be biased at V/2.

With this approach, there is no bias voltage between the unselected rows and unselected columns. This reduces background leakage current.

After biasing the array in this manner, the memory elements 58 may be programmed and read by whatever means is needed for the particular memory technology involved. A memory element 58 that uses a phase change material may be programmed by forcing the current needed for memory element phase change or the memory array can be read by forcing a lower current to determine the device 58 resistance.

For the case of a phase change memory element 58, programming a given selected bit in the phase change memory array can be as follows. Unselected rows and columns may be biased as described for addressing. Zero volts is applied to the selected row. A current is forced on the selected column with a compliance that is greater than the maximum threshold voltage of the device 56 plus the maximum threshold voltage of the device 58. The current amplitude, duration, and pulse shape may be selected to place the memory element 58 in the desired phase and thus, the desired memory state.

Reading a phase change memory element 58 can be performed as follows. Unselected rows and columns may be biased as described previously. Zero volts is applied to the selected row. A voltage is forced at a value greater than the maximum threshold voltage of the access device 56, but less than the minimum threshold voltage of the device 56 plus the minimum threshold voltage of the element 58 on the selected column. The current compliance of this forced voltage is less than the current that could program or disturb the present phase of the memory element 58. If the phase change memory element 58 is set, the access device 56 switches on and presents a low voltage, high current condition to a sense amplifier. If the phase change memory element is reset, a larger voltage, lower current condition may be presented to the sense amplifier. The sense amplifier can either compare the resulting column voltage to a reference voltage or compare the resulting column current to a reference current.

The above-described reading and programming protocols are merely examples of techniques that may be utilized. Other techniques may be utilized by those skilled in the art.

To avoid disturbing a set bit of memory element 58 that is a phase change memory, the peak current may equal the threshold voltage of the device 56 minus the holding voltage of the device 56 that quantity divided by the total series resistance including the resistance of the device 56, external resistance of device 58, plus the set resistance of device 58. This value may be less than the maximum programming current that will begin to reset a set bit for a short duration pulse.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a processor-based system including a controller and a phase change memory directly accessible by said controller.

2. The method of claim 1 including forming a processor-based system with a volatile memory coupled to the phase change memory.

3. The method of claim 2 including coupling said volatile memory to said controller and to said phase change memory.

4. The method of claim 2 including transforming said volatile memory to a lower power consumption state during a standby mode.

5. The method of claim 1 including storing an operating system on said phase change memory.

6. The method of claim 2 including transferring data stored on said volatile memory to said phase change memory before powering down said processor-based system.

7. The method of claim 1 including using a phase change memory having an integrated volatile memory.

8. The method of claim 7 including using a phase change memory formed over said volatile memory.

9. The method of claim 2 including using a volatile memory integrated with said controller.

10. The method of claim 2 including using said volatile memory as a cache memory and permanently storing data on said phase change memory.

11. An apparatus comprising:
a phase change memory that is directly accessible by a controller.

12. The apparatus of claim 11 wherein said memory includes chalcogenic memory elements.

13. The apparatus of claim 11 wherein said memory includes cells that include a memory element and a selection device.

14. The apparatus of claim 13 wherein said selection device includes a chalcogenide.

15. The apparatus of claim 11 including a volatile memory coupled to said phase change memory and formed on the same integrated circuit with said phase change memory.

16. The apparatus of claim 15 wherein said volatile memory is directly accessible by said controller.

17. The apparatus of claim 11 wherein said phase change memory stores code to enable said phase change memory to transform a volatile memory to a lower power consumption state during a standby mode.

18. The apparatus of claim 11 wherein said phase change memory stores an operating system.

19. The apparatus of claim 16 including code to transfer data from said volatile memory to said phase change memory before a power down.

20. A system comprising:
a controller;
a volatile memory coupled to said controller; and
a phase change memory coupled directly to said controller.

21. The system of claim 20 wherein said phase change memory includes chalcogenic memory elements.

22. The system of claim 20 wherein said memory includes cells with a memory element and a selection device.

23. The system of claim 22 wherein said selection device includes a chalcogenide.

24. The system of claim 20 wherein said volatile memory is coupled directly to said controller and to said phase change memory.

25. The system of claim 20 wherein said phase change memory stores code to transform said volatile memory to a lower power consumption state during the standby mode.

26. The system of claim 25 wherein said phase change memory stores code to turn off said volatile memory in a standby mode.

27. The system of claim 20 wherein said volatile memory is integrated on the same integrated circuit with said phase change memory.

28. The system of claim 27 wherein said phase change memory is formed over said volatile memory.

29. The system of claim 20 wherein said volatile memory is integrated with said controller.

30. The system of claim 20 wherein said volatile memory is a cache memory and data is permanently stored on said phase change memory.

31. A method comprising:
storing code on a phase change memory to enable said phase change memory to power down a volatile memory during a standby mode.

32. The method of claim 31 including storing an operating system on said phase change memory.

33. The method of claim 31 including storing code to transfer data stored on a volatile memory to said phase change memory before powering down a processor-based system.

34. The method of claim 31 including using a volatile memory as a cache memory and permanently storing data on said phase change memory.

35. An article comprising a medium storing instructions on a phase change memory that, if executed, enable a processor-based system to:
power down a volatile memory during a standby mode.

36. The article of claim 35 further storing instructions on said phase change memory that, if executed, enable the processor-based system to transfer data stored on the volatile memory to the phase change memory before powering down the processor-based system.

37. The article of claim 35 further storing instructions on said phase change memory that, if executed, enable data to be exchanged between the phase change memory and the volatile memory.

38. An apparatus comprising:
a phase change memory array; and
an element to power down a volatile memory during a standby mode.

39. The apparatus of claim 38 wherein said volatile memory is formed on the same integrated circuit with said phase change memory.

40. The apparatus of claim 39 wherein said phase change memory is formed over said volatile memory.

41. The apparatus of claim 40 wherein said volatile memory is a static random access memory.

42. The apparatus of claim 38 wherein said element stores software to power down a volatile memory during a standby mode.

43. The apparatus of claim 38 wherein said element stores code to cause information to be transferred from a volatile memory to said phase change memory before system power down.

44. The apparatus of claim 38 including a volatile memory and a bus between said volatile memory and said phase change memory to enable data to be exchanged directly between said phase change memory and said volatile memory.
